(19) United States
(12) Patent Application Publication
(10) Pub. No.: US 2023/0335526 A1
(43) Pub. Date: Oct. 19, 2023

(54) HIGH-DENSITY-INTERCONNECTION PACKAGING STRUCTURE AND METHOD FOR PREPARING SAME

(71) Applicant: SJ Semiconductor(Jiangyin) Corporation, Jiangyin City (CN)

(72) Inventors: Chengchung Lin, Jiangyin City (CN); Jin Yang, Jiangyin City (CN)

(21) Appl. No.: 18/132,602

(22) Filed: Apr. 10, 2023

(30) Foreign Application Priority Data
Apr. 15, 2022 (CN) 202210398244.4

(51) Int. Cl. H01L 23/00; H01L 23/31; H01L 25/065; H01L 21/56

(52) U.S. Cl. CPC H01L 24/20; H01L 24/19; H01L 23/3157; H01L 25/0655; H01L 21/56; H01L 2224/2101; H01L 2224/19

(57) ABSTRACT

A high-density-interconnection (HDI) packaging structure and a method for preparing the same are provided. The method comprises: disposing a first metal array with a first pitch and a second metal array with a second pitch on chips; disposing a third metal array on a silicon connector, and bonding the silicon connector to cross the chips; forming a molding layer to cover the chips and the silicon connector; grinding the molding layer and the silicon connector to form ultra-thin silicon; forming vias in the molding layer, with the vias aligned to the second metal array; filling the vias with metal materials, wherein the metal materials are connected to the second metal array; forming metal pillars and connecting the metal pillars to an organic substrate. The present disclosure uses ultra-thin silicon as an intermediate connector to achieve fine interconnection between HDI chips at a pitch of 10 um or less.

### CROSS REFERENCE TO RELATED APPLICATION

The present application claims the benefit of priority to Chinese Patent Application No. CN 202210398244.4, entitled “HIGH-DENSITY-INTERCONNECTION PACKAGING STRUCTURE AND METHOD FOR PREPARING SAME”, filed with CNIPA on Apr. 15, 2022, the disclosure of which is incorporated herein by reference in its entirety for all purposes.

### FIELD OF TECHNOLOGY

The present disclosure relates to semiconductor packaging technology, and in particular to a high-density-interconnection (HDI) packaging structure and a method for preparing the same.

### BACKGROUND

As the cost of integrated circuits (IC) manufactured at advanced process nodes (e.g., 7 nm, 5 nm and beyond) is rising rapidly, die disaggregation technology among other things has become a new technological frontier. Driven by high-speed and high-bandwidth applications, there is an urgent need to develop high-density chip-interconnecting packaging structures. Lately Intel Corp. has proposed an embedded multiple-die interconnection bridge (EMIB) structure, where silicon bridges are embedded into an organic substrate to achieve fine-pitch interconnections between chips. In this structure, the minimum interconnection pitch has been reduced first from 55 μm to 45 μm, and then to 36 μm.

In order to achieve interconnections with higher density, some other packaging structures have been proposed that utilize a silicon interposer as a supporter onto which multiple chips can be assembled. However, with further development of the electronics industry, more chips need to be integrated onto the silicon interposer, demanding larger interposers sizes with time. Silicon interposers of 2400 mm² size have been reported, and interposers with an area larger than 3000 mm² have been proposed. Predictably, this will significantly increase the total cost of the 2.5D/3D IC packaging and the cost of materials that will increase with size.

Therefore, to achieve high-density chip-interconnecting structures with reduced the interconnection pitch within a limited area is an urgent problem facing those working in the packaging technology.

### SUMMARY

The present disclosure provides a method for preparing an HDI packaging structure, comprising: 1) providing at least two chips, disposing a first metal array with a first pitch and a second metal array with a second pitch over each of the two chips; 2) providing a silicon connector, disposing a third metal array over the silicon connector, and bonding the silicon connector across the chips by arranging to connect the third metal array and the first metal array; 3) forming a molding layer, covering the chips and the silicon connector; 4) grinding the molding layer to expose the silicon connector first, then continuing to grind the silicon connector until the silicon connector becomes ultra-thin silicon; 5) forming vias in the molding layer, wherein the vias are aligned to the second metal array, filling the vias with metal materials, wherein the metal materials are connected to the second metal array; and 6) forming metal pillar structures over the metal-filled vias, wherein the metal pillar structures are connected to the metal materials in the vias, and wherein the metal pillar structures are also connected to an organic substrate.

The present disclosure also provides an HDI packaging structure, comprising: at least two chips, wherein a first metal array with a first pitch and a second metal array with a second pitch are disposed over each of said chips; an ultra-thin silicon, wherein a third metal array is disposed over the ultra-thin silicon, wherein the third metal array and the first metal array are aligned to each other and are bonded together; a molding layer, covering the at least two chips and the ultra-thin silicon; vias, formed in the molding layer and aligned to the second metal array; metal materials, filled in the vias and connected to the second metal array; metal pillar structures, formed over the filled vias and connected to the metal materials in the filled vias; and an organic substrate, connected to the metal pillar structures.

The present disclosure uses ultra-thin silicon as an intermediate connector to achieve fine interconnections between HDI chips with a pitch of 10 μm or less; in areas that have little or no relevance to chip interconnection, the second metal array with a larger pitch D2 is used to connect the chip and the organic substrate, thereby reducing the packaging cost and achieving 2.5D/3D IC packaging with high-performance and high-bandwidth. In addition, in the present disclosure, ordinary vias, instead of expensive through-silicon-vias, are formed in the molding layer, thereby further reducing the manufacturing cost.

### BRIEF DESCRIPTION OF THE DRAWINGS

FIGS. 1 to 10 are schematic cross-sectional diagrams of intermediate structures obtained after each major step following the method in preparing an HDI packaging structure according to the present disclosure, wherein FIG. 10 is a schematic cross-sectional diagram of the HDI packaging structure according to the present disclosure.

### DETAILED DESCRIPTION

The following describes the implementation of the present disclosure through specific examples, and those skilled in the art can easily understand other advantages and effects of the present disclosure from the content disclosed in this specification. The present disclosure can also be implemented or applied through other different specific examples. Various details in this specification can also be modified or changed based on different viewpoints and applications without departing from the spirit of the present disclosure.

Please refer to the drawings. It should be noted that the drawings provided in this disclosure only illustrate the basic concept of the present disclosure in a schematic way, so the drawings only show the components related to the present disclosure. The drawings are not necessarily drawn according to the number, shape and size of the components in actual implementation; during the actual implementation, the type, quantity and proportion of each component can be changed as needed, and the components' layout may also be more complicated.

### Example 1

The present disclosure provides a method for preparing a high-density-interconnection (HDI) packaging structure, comprising operational steps described below:

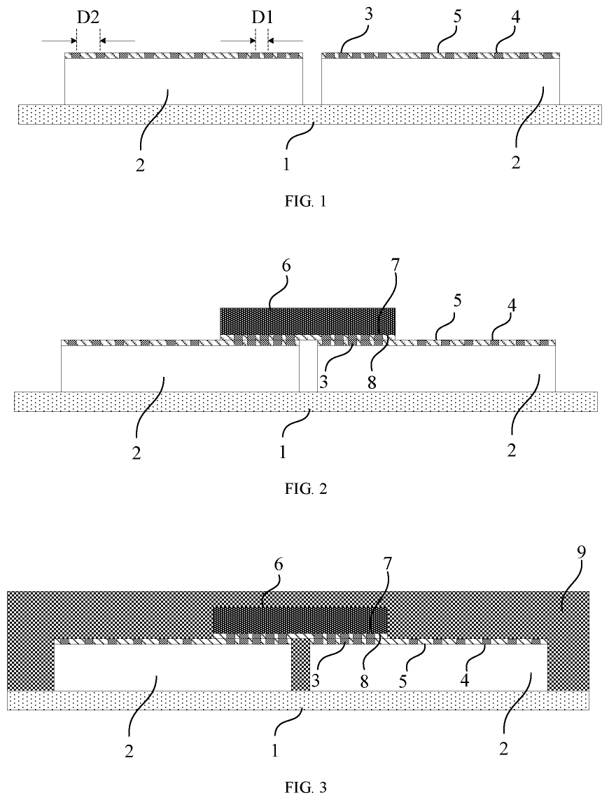

Operation 1): providing two chips, wherein a first metal array with a first pitch and a second metal array with a second pitch are disposed over each of the chips, as shown in FIG. 1.

The two chips 2 may be semiconductor chips suitable for packaging, and may include more than two chips of the same type or multiple different types; for example, the chips 2 may be system-on-chip (SOC) devices, or memory chips, such as HBM, etc. In addition, based on requirements of package efficiency, package size, etc., the chips 2 are generally packaged together; in most cases, there are more than two chips 2; herein, the drawings disclose two chips as an example.

As an example, the first pitch D1 is less than or equal to 10 μm. Preferably, the first pitch D1 is in a range between 1 μm and 10 μm. In one example, the first pitch is about 9 μm. In another example, the first pitch is about 1 μm. It is to be noted that the first pitch D1 is the distance between centers of two adjacent metal points of the first metal array as disclosed in FIG. 1.

As an example, the second pitch D2 is in a range between 20 μm and 150 μm. Preferably, the second pitch is between 80 μm and 150 μm. In one example, the second pitch is around 100 μm. In another example, the second pitch is around 120 μm. It is to be noted that the second pitch D2 is the distance between centers of two adjacent metal points of the second metal array, as shown in FIG. 1.

As an example, as shown in FIG. 1, a first dielectric layer 5 is disposed over the chips 2, and the first metal array 3 and second metal array 4 are formed in the first dielectric layer 5. The first dielectric layer 5 may be made of one or more of SiO₂, SiN, and SiCN. In one example, the first dielectric layer 5 is made of SiO₂.

In some examples, the chips 2 may be placed on a carrier 1; the carrier 1, for example, is made of glass. In some examples, the t chips 2 are disposed on the carrier 1 using the Pick and Place method.

Prior to performing operation 2), a chemical mechanical polishing (CMP) process may also be performed on a surface of the chips 2 to polish surfaces of the first metal array 3, the second metal array 4, and the first dielectric layer 5.

Operation 2) providing a silicon connector 6, wherein a third metal array 7 is disposed over the silicon connector 6, and the silicon connector 6 is bonded to the chips 2 through the third metal array 7 and the first metal array 3, as shown in FIG. 2.

As an example, as shown in FIG. 2, a second dielectric layer 8 is formed over the silicon connector 6 and the third metal array 7 is formed in the second dielectric layer 8. The second dielectric layer 8 may be one or more of SiO₂, SiN, and SiCN. In one example, the second dielectric layer 8 is made of SiO₂.

As an example, as shown in FIG. 2, the silicon connector 6 is bonded to the chips 2 by surface hybrid bonding, wherein the third metal array 7 and the first metal array 3 are aligned to each other and are bonded together, and a portion of the first dielectric layer 5 located under the silicon connector 6 and the second dielectric layer 8 are aligned to each other and are bonded together. Surface hybrid bonding is a bonding method whose bonding interfaces include both metal materials and insulating materials, by surface hybrid bonding, two wafers can be connected by proximity atomic bonding without adhesive medium, thereby realizing interconnection of multiple chips, greatly improving chip performance, saving area, reducing costs, and achieving the purpose of fine-pitch interconnection between metal arrays.

Operation 3): forming a molding layer 9, covering the chips 2 and the silicon connector 6, as shown in FIG. 3.

As an example, the molding layer 9 may be made of one or more of an epoxy, resin, plasticizable polymer and the like. Methods for preparing the molding layer 9 include, but are not limited to, compression molding, transfer molding, liquid seal molding, mold underfill, capillary underfill, vacuum lamination, or spin coating.

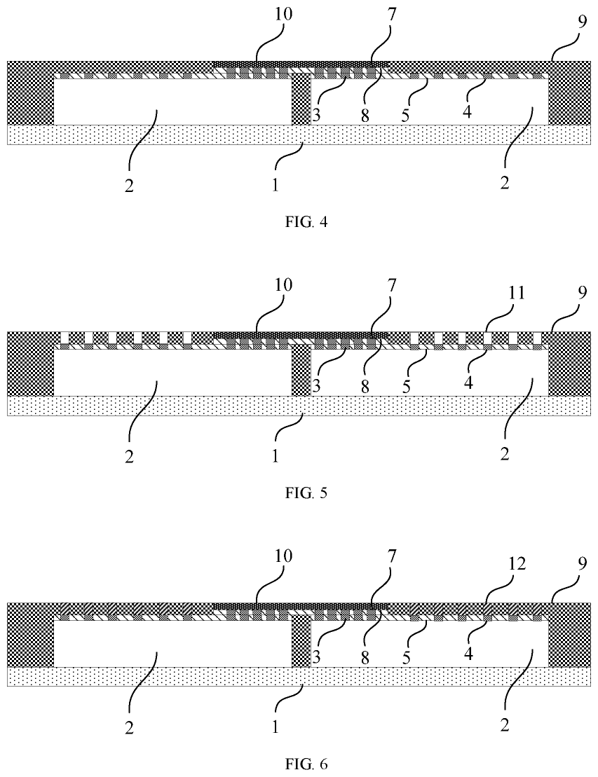

Operation 4): grinding the molding layer 9 by steps and first let the top surface of the silicon connector 6 be exposed, then continue to grind the silicon connector 6 so that the silicon connector 6 becomes ultra-thin silicon 10, as shown in FIG. 4.

As an example, the thickness of the ultra-thin silicon 10 is less than or equal to 30 μm. By preparing the ultra-thin silicon 10 and molding layer 9 with such a low thickness, the package size can be further reduced.

Operation 5): forming vias 11 in the molding layer 9, wherein the vias 11 are aligned to the second metal array 4 as shown in FIG. 5, filling the vias 11 with metal materials 12, wherein the metal materials 12 are connected to the second metal array 4 as shown in FIG. 6.

As an example, the vias 11 have a depth-to-diameter ratio between 3:1 and 5:1. The molding layer 9 after grinding is relatively thin, which reduced the vias 11 depth-to-diameter aspect ratio, which can be preferably 3:1, 4:1, 5:1, etc.

As an example, the metal materials 12 may include one or more of copper, aluminum, nickel, gold, silver, titanium, etc. Deposition methods for filling the metal materials 12 include, but are not limited to electroplating method. In one example, the metal materials 12 are made of electroplated copper.

In addition, in Operation 5), vias 11 through the molding layer 9, instead of expensive through-silicon-vias (TSVs), are formed, thereby further reducing the manufacturing cost.

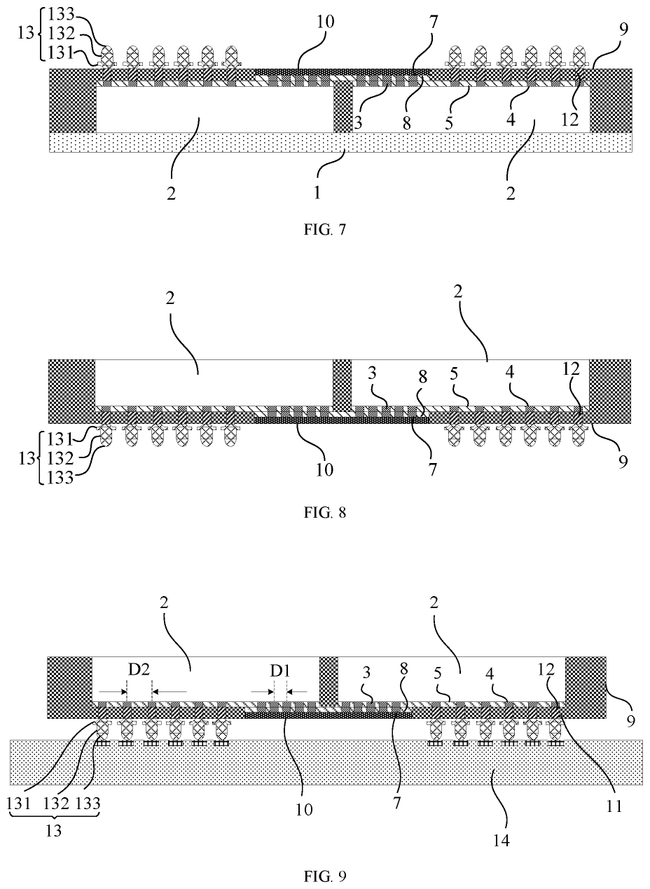

Operation 6): forming metal pillar structures 13 over the metal-filled vias 11, wherein the metal pillar structures 13 are connected to the metal materials 12, as shown in FIG. 7, and the metal pillar structures 13 are also connected to an organic substrate 14 as shown in FIG. 9.

In some examples, the glass carrier 1 can be removed before connecting the metal pillar structures 13 to the organic substrate 14, as shown in FIG. 8.

As an example, forming metal pillar structures 13 over metal-filled vias 11 includes: first, forming bumps 131 connected to the metal materials 12 over the top surface of the metal-filled vias 11; then, forming metal pillars 132 on the bumps 131; and finally, forming solder caps 133 on the metal pillars 132. The bumps 131 may be Under Bump Metal (UBM).

The materials of the bumps 131 and the metal pillars 132 include one or more of titanium, copper, nickel, tin, and silver. In one example, the materials of the bumps 131 and the metal pillars 132 are both copper.

As an example, the metal pillar structures 13 can be attached to the organic substrate 14 by a reflow and thermal compression bond (TCB) process. As an example, the metal pillar structures 13 can be attached to a metal array on the organic substrate 14 by the reflow and TCB process, thereby achieving electrical connection between the two.

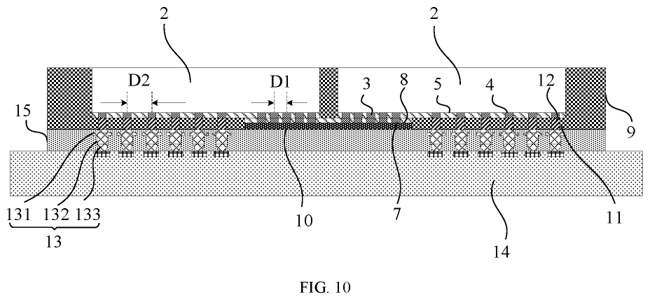

Alternatively, as shown in FIG. 10, the method, after operation 6), includes an operation of forming an underfill layer 15 between the organic substrate 14 and the molding layer 9 and between the organic substrate 14 and the ultra-thin silicon 10, to encapsulate the metal pillar structures 13. The underfill layer 15 improves the bonding strength between the organic substrate 14 and the molding layer 9, and the bonding strength between the organic substrate 14 and the ultra-thin silicon 10, and protects the metal pillar structures 13 from contamination. The material of the underfill layer 15 includes, but is not limited to, one or more of polyimide, silicone, and epoxy resin, and the method for forming the underfill layer 15 includes, but is not limited to, one or more of ink jet printing, dispensing, compression molding, transfer molding, liquid seal molding, vacuum lamination, and spin coating.

The present disclosure uses the ultra-thin silicon 10 as an intermediate connector to achieve fine interconnection between the chips 2 with a pitch of 10 μm or less; in areas that have little or no relevance to chip interconnection, the second metal array with a larger pitch D2 is used to connect the chips and the organic substrate 14, thereby reducing the packaging cost and achieving 2.5D/3D IC packaging with high-performance and high-bandwidth.

### Example 2

As shown in FIG. 10, the present disclosure also provides an HDI packaging structure, which may be prepared by the method of Embodiment 1.

The HDI packaging structure includes: chips 2, wherein a first metal array 3 with a first pitch D1 and a second metal array 4 with a second pitch D2 are disposed over each of the chips; ultra-thin silicon 10, wherein a third metal array 7 is disposed over the ultra-thin silicon 10, the third metal array 7 and the first metal array 3 are aligned to each other and are bonded together; a molding layer 9, covering the chips 2 and the ultra-thin silicon 10; vias 11, formed in the molding layer 9 and are aligned to the second metal array 4; metal materials 12, filled in the vias 11 and connected to the second metal array 4; metal pillar structures 13, formed over the vias 11 and connected to the metal materials 13; and an organic substrate, connected to the metal pillar structures 13.

The chips 2 may be any semiconductor chips suitable for packaging, and may include of the same type or a plurality of different types; for example, the chips 2 may be a system-on-chip (SOC) device, or memory chips, such as high-bandwidth-memory (HBM) chips, etc. In addition, based on requirements of package efficiency, package size, etc., chips 2 will generally be packaged together; in most cases, there will be y more than two chips 2; herein, the drawings take two chips as an example.

As an example, the first pitch is less than or equal to 10 μm. Preferably, the first pitch is between 5 μm and 10 μm. In one example, the first pitch is around 6 μm. In another example, the first pitch is around 8 μm.

As an example, the second pitch is in a range of between 20 μm and 150 μm. Preferably, the second pitch is in a range between 80 μm and 150 μm. In one example, the second pitch is around 100 μm. In another example, the second pitch is around 120 μm.

As an example, the HDI packaging structure further includes a first dielectric layer 5 and a second dielectric layer 8, wherein the first dielectric layer 5 is formed over the two chips 2, the first metal array 3 and the second metal array 4 are formed in the first dielectric layer 5, the second dielectric layer 8 is formed over the ultra-thin silicon 10, and the third metal array 7 is formed in the second dielectric layer 8. The second dielectric layer 8 may be made of one or more of SiO₂, SiN, and SiCN. In one example, the second dielectric layer 8 is made of SiO₂.

As an example, the thickness of the ultra-thin silicon 10 is less than or equal to 30 μm. By preparing the ultra-thin silicon 10 and a thin molding layer 9, the package size can be further reduced.

As an example, the molding layer 9 may be made of one or more of an epoxy, resin, plasticizable polymer and the like. Methods for preparing the molding layer 9 include, but are not limited to, compression molding, transfer molding, liquid seal molding, mold underfill, capillary underfill, vacuum lamination, or spin coating.

As an example, the vias 11 have a length to diameter ratio between 3:1 and 5:1. The molding layer 9 is relatively thin, which makes the vias 11 have a smaller depth-to-diameter aspect ratio, which can be preferably 3:1, 4:1, 5:1, etc.

As an example, the metal materials 12 may include one or more of copper, aluminum, nickel, gold, silver, titanium, etc. Methods for filling the metal materials 12 include, but are not limited to, deposition methods, electroplating methods, etc. In one example, the metal materials 12 are made of electroplated copper.

As an example, each of the metal pillar structures 13 includes a bump 131, a metal pillar 132 and a solder cap 133, wherein the bump 131 is formed over one of the vias 11 and connected to the metal materials 12, the metal pillar 132 is formed on the bump 131, and the solder cap 133 is formed on the metal pillar 132. The materials of the bumps 131 and the metal pillars 132 include one or more of titanium, copper, nickel, tin, and silver. In one example, the materials of the bumps 131 and the metal pillars 132 are both copper.

In addition, the packaging structure further comprises a underfill layer 15 formed between the organic substrate 14 and the molding layer 9, and between the organic substrate 14 and the ultra-thin silicon 10, to encapsulate the metal pillar structures 13. The underfill layer 15 improves the bonding strength between the organic substrate 14 and the molding layer 9, and the bonding strength between the organic substrate 14 and the ultra-thin silicon 10, and protects the metal pillar structures 13 from contamination. The material of the underfill layer 15 includes, but is not limited to, one or more of polyimide, silicone, and epoxy resin, and the method for forming the underfill layer 15 includes, but is not limited to, one or more of ink jet printing, dispensing, compression molding, transfer molding, liquid seal molding, vacuum lamination, and spin coating.

In summary, the present disclosure provides a high-density-interconnection packaging structure and a method for preparing the same, and the method includes: providing at least two chips 2, wherein a first metal array 3 with a first pitch and a second metal array 4 with a second pitch are disposed over each chip; providing a silicon connector 6, wherein a third metal array 7 is disposed over the silicon connector 6, and the silicon connector 6 is bonded to the chips 2 through the third metal array 7 and the first metal array 3; forming a molding layer 9, covering the chips 2 and the silicon connector 6; grinding the molding layer 9 until the silicon connector 6 is exposed, and then continuing to grind the silicon connector 6 so that the silicon connector 6 becomes ultra-thin silicon; forming vias 11 in the molding layer 9, wherein the vias 11 aligned to the second metal array 4, filling the vias 11 with metal materials 12, wherein the metal materials 12 are connected to the second metal array 4; and forming metal pillar structures 13 over openings of the vias 11, wherein the metal pillar structures 13 are connected to the metal materials 12, and the metal pillar structures 13 are also connected to an organic substrate 14. The present disclosure uses the ultra-thin silicon 10 as an intermediate connector to achieve fine interconnection between the chips 2 with a pitch of 10 μm or less; in areas that have little or no relevance to chip interconnection, the second metal array with a larger pitch D2 is used to connect the chips and the organic substrate 14, thereby reducing the packaging cost and achieving 2.5D/3D IC packaging with high-performance and high-bandwidth.

Therefore, the present disclosure effectively overcomes various shortcomings of the prior art and has a high industrial value.

The above-mentioned examples only exemplarily illustrate the principles and effects of the present disclosure, but are not used to limit the present disclosure. Any person skilled in the art may modify or change the above examples without violating the spirit and scope of the present disclosure. Therefore, all equivalent modifications or changes made by those skilled in the art without departing from the spirit and technical concepts disclosed by the present disclosure should still be covered by the attached claims of the present disclosure.

What is claimed is:

1. A method for preparing a high-density-interconnection (HDI) packaging structure for semiconductor chips, comprising:
1) providing at least two chips, disposing a first metal array with a first pitch and a second metal array with a second pitch over each of the two chips;
2) providing a silicon connector, disposing a third metal array over the silicon connector, and bonding the silicon connector across the chips by arranging to connect the third metal array and the first metal array;
3) forming a molding layer, covering the chips and the silicon connector;
4) grinding the molding layer to expose the silicon connector first, then continuing to grind the silicon connector until the silicon connector becomes ultra-thin silicon;
5) forming vias in the molding layer, wherein the vias are aligned to the second metal array, filling the vias with metal materials, wherein the metal materials are connected to the second metal array; and
6) forming metal pillar structures over the metal-filled vias, wherein the metal pillar structures are connected to the metal materials in the vias, and wherein the metal pillar structures are also connected to an organic substrate.

2. The method for preparing the HDI packaging structure according to claim 1, wherein in operation 1) the first pitch is less than or equal to 10 μm.

3. The method for preparing the HDI packaging structure according to claim 1, wherein in operation 1) the second pitch is in a range between 20 μm and 150 μm.

4. The method for preparing the HDI packaging structure according to claim 1, wherein the operation 1) further comprises: disposing a first dielectric layer over the chips, wherein the first metal array and the second metal array are formed in the first dielectric layer; wherein the operation 2) further comprises disposing a second dielectric layer over the silicone connector, wherein the third metal array is formed in the second dielectric layer.

5. The method for preparing the HDI packaging structure according to claim 4, wherein the operation 2) further comprises arranging to connect the third metal array and the first metal array by surface hybrid bonding, wherein the third metal array and the first metal array are aligned to each other and are bonded together, and wherein the first dielectric layer located under the silicon connector and the second dielectric layer are aligned to each other and are bonded together.

6. The method for preparing the HDI packaging structure according to claim 1, wherein in operation 4) a thickness of the ultra-thin silicon is less than or equal to 30 μm.

7. The method for preparing the HDI packaging structure according to claim 1, wherein in operation 5) the vias have a depth-to-diameter aspect ratio in a range of 3:1 to 5:1.

8. The method for preparing the HDI packaging structure according to claim 1, wherein the operation 6) of forming the metal pillar structures over the filled vias further comprises: first, forming bumps connected to the metal materials of the vias; forming metal pillars on the bumps; and finally, forming solder caps on the metal pillars.

9. A high-density-interconnection (HDI) packaging structure for semiconductor chips, comprising:
at least two chips, wherein a first metal array with a first pitch and a second metal array with a second pitch are disposed over each of said chips;
an ultra-thin silicon, wherein a third metal array is disposed over the ultra-thin silicon, wherein the third metal array and the first metal array are aligned to each other and are bonded together;
a molding layer, covering the at least two chips and the ultra-thin silicon;
vias, formed in the molding layer and aligned to the second metal array;
metal materials, filled in the vias and connected to the second metal array;
metal pillar structures, formed over the filled vias and connected to the metal materials in the filled vias; and
an organic substrate, connected to the metal pillar structures.

10. The HDI packaging structure according to claim 9, wherein the first pitch is less than or equal to 10 μm.

11. The HDI packaging structure according to claim 9, wherein the second pitch is in the range of 20 μm to 150 μm.

12. The HDI packaging structure according to claim 9, further comprising a first dielectric layer and a second dielectric layer, wherein the first dielectric layer is formed over said chips, wherein the first metal array and the second metal array are formed in the first dielectric layer, wherein the second dielectric layer is formed over the ultra-thin silicon, and wherein the third metal array is formed in the second dielectric layer.

13. The HDI packaging structure according to claim 9, wherein a thickness of the ultra-thin silicon is less than or equal to 30 μm.

14. The HDI packaging structure according to claim 9, wherein the vias have a depth-to-diameter aspect ratio in a range between 3:1 and 5:1.

15. The HDI packaging structure according to claim 9, wherein each of the metal pillar structures comprises a bump, a metal pillar, and a solder cap, wherein the bump is formed over one of the filled vias and connected to the metal materials, wherein the metal pillar is formed on the bump, and wherein the solder cap is formed on the metal pillar.
